(19) United States
(12) Patent Application Publication
(10) Pub. No.: US 2026/0223306 A1
(43) Pub. Date: Jul. 30, 2026

(54) ELECTRONIC DEVICE INCLUDING COVER GLASS CONNECTION FRAME

(71) Applicant: Samsung Electronics Co., Ltd., Suwon-si (KR)

(72) Inventors: Hyunjune YANG, Suwon-si (KR); Gwangchae JUNG, Suwon-si (KR); Dohyung HA, Suwon-si (KR); Hyoksu CHOI, Suwon-si (KR)

(21) Appl. No.: 19/577,918

(22) Filed: Mar. 25, 2026

Related U.S. Application Data
(63) Continuation of application No. PCT/KR2024/010667, filed on Jul. 24, 2024.

(30) Foreign Application Priority Data
Oct. 10, 2023 (KR) 10-2023-0134224
Nov. 21, 2023 (KR) 10-2023-0162620

(51) Int. Cl. H05K 5/03; H05K 5/02

(52) U.S. Cl. CPC H05K 5/03; H05K 5/0217

(57) ABSTRACT

An electronic device is provided. The electronic device includes a housing including a first surface, a second surface opposite to the first surface, and a side member surrounding at least a portion of an inner space between the first surface and the second surface, cover glass disposed on the first surface of the housing, a connection member connected to the inside of the side member and supporting at least a portion of the cover glass, and a support member connected to the connection member and supporting an edge of the cover glass, wherein the surfaces of the cover glass and the support member may protrude in the direction faced by the first surface, compared to the surface of the side member.

### CROSS-REFERENCE TO RELATED APPLICATION(S)

This application is a continuation application, claiming priority under 35 U.S.C. § 365(c), of an International application No. PCT/KR2024/010667, filed on July 24, 2024, which is based on and claims the benefit of a Korean patent application number 10-2023-0134224, filed on October 10, 2023, in the Ministry of Intellectual Property (MOIP), and of a Korean patent application number 10-2023-0162620, filed on November 21, 2023, in the Ministry of Intellectual Property (MOIP), the disclosure of each of which is incorporated by reference herein in its entirety.

### BACKGROUND

### 1. Field

The disclosure relates to an electronic device including a cover glass connection frame.

### 2. Description of Related Art

A cover glass is disposed on a front surface and a rear surface of an electronic device such as a mobile device or a tablet. A cover glass connection frame connects the cover glass to a housing of the electronic device. When the connection frame is made of an opaque material, an interior of the housing is blocked from view, but a sense of heterogeneity occurs between the cover glass and the connection frame. In consideration of aesthetics and durability of the cover glass, a new structure of the cover glass connection frame is needed. The above description has been possessed or acquired by the inventor(s) in the course of conceiving the disclosure and is not necessarily an art publicly known before the application is filed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a n electronic device including a cover glass connection frame.

Additional aspects will be set forth in part in the description which follows and, in part, will be apparent from the description, or may be learned by practice of the presented embodiments.

In accordance with an aspect of the disclosure, an electronic device is provided. The electronic device includes a housing including a first surface, a second surface opposite to the first surface, and a side member surrounding at least a portion of an inner space between the first surface and the second surface, a cover glass disposed on the first surface of the housing, a connection member connected to an inside of the side member and configured to support at least a portion of the cover glass, and a support member connected to the connection member and configured to support an edge of the cover glass, wherein surfaces of the cover glass and the support member protrude in a direction the first surface faces, compared to a surface of the side member.

In accordance with another aspect of the disclosure, an electronic device is provided. The electronic device includes a housing including a first surface, a second surface opposite to the first surface, and a side member surrounding at least a portion of an inner space between the first surface and the second surface, a first cover glass disposed on the first surface, a second cover glass disposed on the second surface, a first connection member connected to an inside of the side member and configured to support at least a portion of the first cover glass, a second connection member connected to an inside of the side member and configured to support at least a portion of the second cover glass, a first support member connected to the first connection member and configured to support an edge of the first cover glass, and a second support member connected to the second connection member and configured to support an edge of the second cover glass, wherein surfaces of the first cover glass and the first support member protrude in a direction the first surface faces, compared to a surface of the side member, and wherein surfaces of the second cover glass and the second support member protrude in a direction the second surface faces, compared to the surface of the side member.

In accordance with an aspect of the disclosure, an electronic device is provided. The electronic device includes a housing including a first surface, a second surface opposite to the first surface, and a side member surrounding at least a portion of an inner space between the first surface and the second surface, a display disposed on the first surface of the housing, a cover glass disposed on the second surface of the housing, a connection member connected to an inside of the side member and configured to support at least a portion of the cover glass, and a support member formed of a transparent material, connected to the connection member, and configured to support an edge of the cover glass, wherein surfaces of the cover glass and the support member protrude in a direction the second surface faces, compared to a surface of the side member, wherein the support member includes a first support portion configured to support a rear surface of the cover glass, and a second support portion extending outward from the first support portion and configured to support an edge of the cover glass, wherein the second support portion protrude further in a direction the second surface faces than the first support portion.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2A is a front perspective view of an electronic device according to an embodiment of the disclosure;

FIG. 2B is a rear perspective view of an electronic device according to an embodiment of the disclosure;

FIG. 3 is an exploded perspective view of an electronic device according to an embodiment of the disclosure;

FIG. 4 is a partial cross-sectional view illustrating a side member, a connection member, a support member, and a cover glass of an electronic device according to an embodiment of the disclosure;

FIG. 5 is a partial cross-sectional view illustrating a side member, a connection member, a support member, and a cover glass of an electronic device according to an embodiment of the disclosure;

FIG. 6A is an enlarged cross-sectional view of a region A illustrated in FIG. 4 according to an embodiment of the disclosure;

FIG. 6B is an enlarged cross-sectional view of a region B illustrated in FIG. 4 according to an embodiment of the disclosure;

FIG. 6C is an enlarged cross-sectional view of a region C illustrated in FIG. 4 according to an embodiment of the disclosure;

FIG. 7 is a partial cross-sectional view illustrating a side member, a connection member, a support member, a display, and a cover glass of an electronic device according to an embodiment of the disclosure; and

FIG. 8 is a cross-sectional view illustrating a side member, a connection member, a support member, and a cover glass of an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

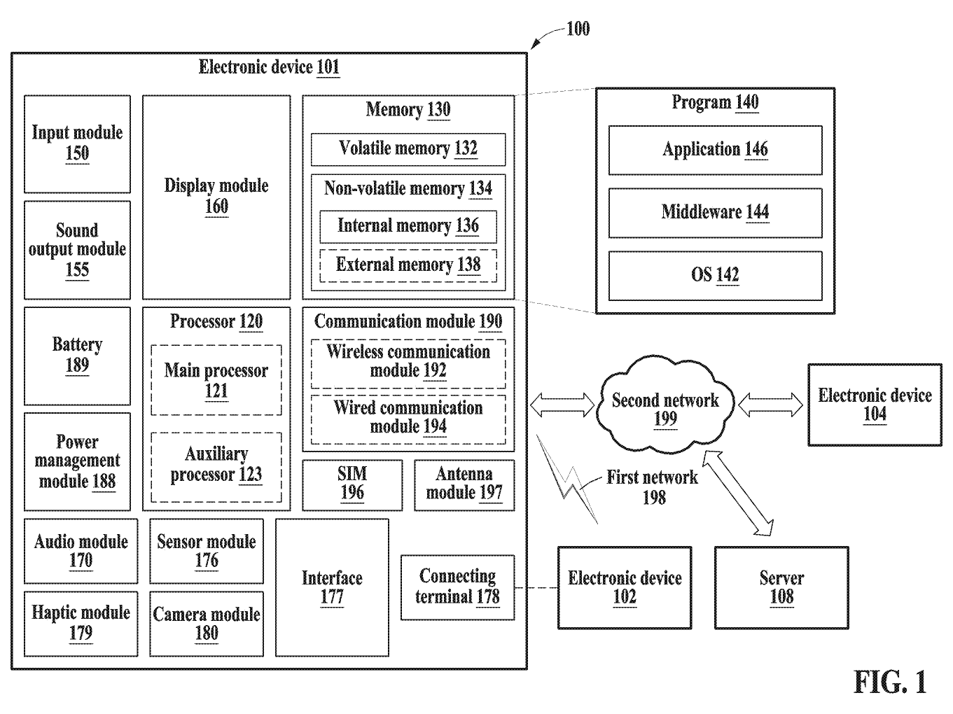

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added to the electronic device 101. In some embodiments, some of the components (e.g., the sensor module 176, the camera module 180, or the antenna module 197) may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an ISP or a CP) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., an electronic device 102) (e.g., a speaker or a headphone) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly or wirelessly. According to an embodiment, the interface 177 may include, for example, a high definition multimedia interface (HDMI), a universal serial bus (USB) interface, a secure digital (SD) card interface, or an audio interface.

The connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, ISPs, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., the AP) and support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., a LAN or a wide area network (WAN)). These various types of communication modules may be implemented as a single component (e.g., a single chip), or may be implemented as multiple components (e.g., multiple chips) separate from each other. The wireless communication module 192 may identify or authenticate the electronic device 101 in a communication network, such as the first network 198 or the second network 199, using subscriber information (e.g., international mobile subscriber identity (IMSI)) stored in the SIM 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., an external electronic device). According to an embodiment, the antenna module 197 may include an antenna including a radiating element composed of a conductive material or a conductive pattern formed in or on a substrate (e.g., a printed circuit board (PCB)). According to one embodiment, the antenna module 197 may include a plurality of antennas (e.g., array antennas). In such a case, at least one antenna appropriate for a communication scheme used in a communication network, such as the first network 198 or the second network 199, may be selected by, for example, the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a PCB, an RFIC disposed on a first surface (e.g., a bottom surface) of the PCB, or adjacent to the first surface and capable of supporting a designated high-frequency band (e.g., the mmWave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 or 104 may be a device of the same type as, or a different type, from the electronic device 101. According to an embodiment, all or some of operations to be executed by the electronic device 101 may be executed by one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, cloud computing, distributed computing, mobile edge computing (MEC), or client-server computing technology may be used, for example. The electronic device 101 may provide ultra-low latency services using, e.g., distributed computing or mobile edge computing. In another embodiment, the external electronic device 104 may include an Internet-of-Things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to the embodiments disclosed herein may be one of various types of electronic devices. The electronic devices may include, for example, a portable communication device (e.g., a smart phone), a computer device, a portable multimedia device, a portable medical device, a camera, a wearable device, or a home appliance. According to an embodiment of the disclosure, the electronic devices are not limited to those described above.

It should be appreciated that embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as "A or B," "at least one of A and B," "at least one of A or B," "A, B, or C," "at least one of A, B, and C," and "at least one of A, B, or C," may include any one of, or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively," as "coupled with," "coupled to," "connected with," or "connected to" another element (e.g., a second element), it means that the element may be coupled with the other element directly (e.g., by wire), wirelessly, or via a third element.

As used in connection with various embodiments of the disclosure, the term "module" may include a unit implemented in hardware, software, or firmware, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., an internal memory 136 or an external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment disclosed herein may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

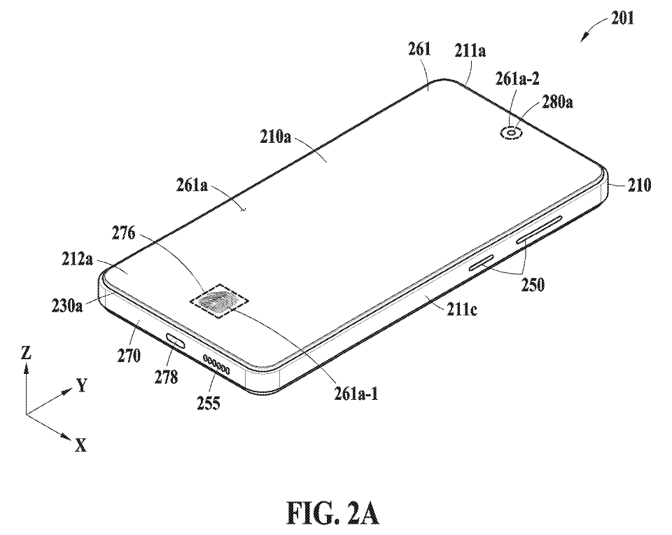

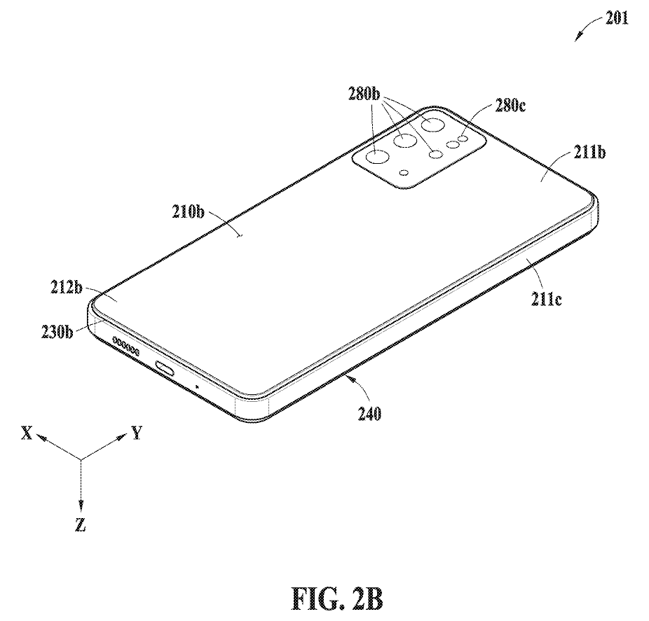

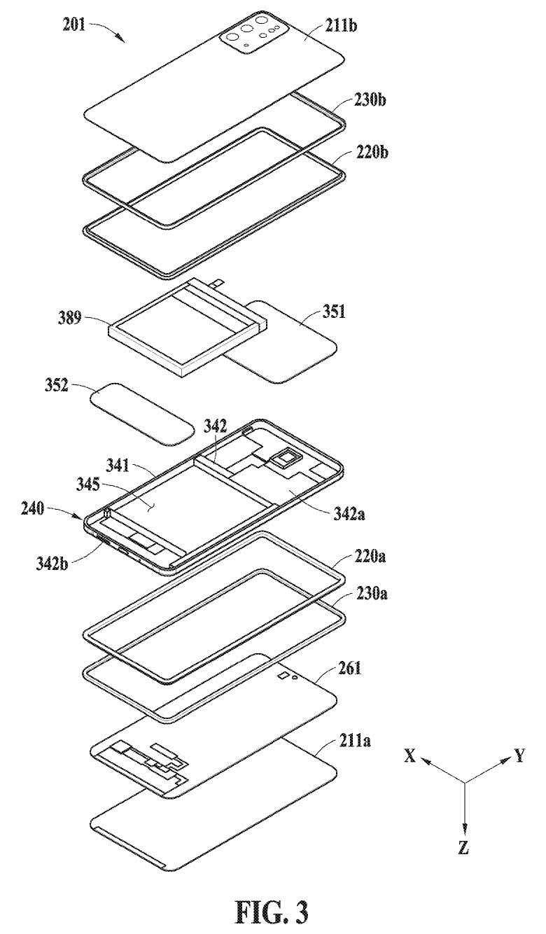

FIG. 2A is a front perspective view of an electronic device according to an embodiment of the disclosure, FIG. 2B is a rear perspective view of the electronic device according to an embodiment of the disclosure, and FIG. 3 is an exploded perspective view of the electronic device according to an embodiment of the disclosure.

Referring to FIGS. 2A, 2B, and 3, an electronic device 201 (e.g., the electronic device 101 of FIG. 1) according to an embodiment may include a housing 210 having a front surface 210a, a rear surface 210b, and a side surface 211c surrounding an internal space between the front surface 210a and the rear surface 210b.

In an embodiment, the front surface 210a may be formed by a first plate 211a of which at least a portion is substantially transparent. For example, the first plate 211a may include a polymer plate or a glass plate including at least one coating layer. In an embodiment, the rear surface 210b may be formed by a second plate 211b that is substantially opaque. For example, the second plate 211b may be formed of coated or tinted glass, ceramic, polymer, metal (e.g., aluminum, stainless steel, or magnesium), or a combination thereof. The side surface 211c may be coupled to the first plate 211a and the second plate 211b and may be formed by a side member 240 including metal and/or polymer. In an embodiment, the second plate 211b and the side member 240 may be integrally and seamlessly formed. In an embodiment, the second plate 211b and the side member 240 may be formed of substantially the same material (e.g., aluminum).

In an embodiment, the side member 240 may surround at least a portion of the inner space between the front surface 210a and the rear surface 210b. The side member 240 may include a first support structure 341 disposed on at least a portion of the side surface 211c and a second support structure 342 connected to the first support structure 341 to form a space for disposing the components of the electronic device 201. In an embodiment, the first support structure 341 may connect an edge of the first plate 211a and an edge of the second plate 211b and surround the space between the first plate 211a and the second plate 211b, thereby forming the side surface 211c of the housing 210. In an embodiment, the second support structure 342 may be disposed inside (or in a body portion) of the electronic device 201. The second support structure 342 may be integrally formed with the first support structure 341 or may be formed separately from the first support structure 341 and connected to the first support structure 341. In an embodiment, PCBs 351 and 352 may be disposed in the second support structure 342. The second support structure 342 may be connected to, for example, grounds of the PCBs 351 and 352. In an embodiment, a display 261 may be disposed on one surface (e.g., a bottom surface (a surface in the +Z-axis direction) of FIG. 3) of the second support structure 342, and the second plate 211b may be disposed on the other surface (e.g., a top surface (a surface in the -Z-axis direction) of FIG. 3) of the second support structure 342.

In an embodiment, at least a portion of the side member 240 may be formed of a conductive material. For example, the first support structure 341 may be formed of a metal and/or conductive polymer material. In an embodiment, like the first support structure 341, the second support structure 342 may be formed of a metal and/or conductive polymer material.

In an embodiment, the first plate 211a may include a first cover glass 212a exposed to the exterior of the electronic device 201, and the second plate 211b may include a second cover glass 212b exposed to the exterior of the electronic device 201. In an embodiment, at least one cover glass of the first cover glass 212a and the second cover glass 212b may be connected to the side member 240 of the housing 210 through a cover glass connection frame. In other words, the cover glass connection frame may be disposed on only one of a front surface and a rear surface of the housing 210. With this structure, the first plate 211a and the second plate 211b may be connected to the side member 240 so as to protrude from the housing 210 toward the first surface and the second surface, respectively. For example, the first plate 211a may protrude from the housing 210 in a direction the front surface 210a faces (e.g., a +Z direction), or the second plate 211b may protrude from the housing 210 in a direction the rear surface 210b faces (e.g., a -Z direction).

In an embodiment, the cover glass connection frame connecting the first cover glass 212a to the side member 240 of the housing 210 may include a first connection member 220a and a first support member 230a. The cover glass connection frame connecting the second cover glass 212b to the side member of the housing may include a second connection member 220b and a second support member 230b.

In an embodiment, the first connection member 220a may be connected to an inside of the side member 240 and support at least a portion of the first cover glass 212a. For example, the first connection member 220a may have a structure extending along an inner rim of the side member 240.

In an embodiment, the first support member 230a may be connected to the first connection member 220a and support an edge of the first cover glass 212a. The first support member 230a may have a structure extending along the first connection member 220a. In an embodiment, among surfaces of the first cover glass 212a and the first support member 230a, a surface the front surface 210a faces may protrude further in a direction the front surface 210a faces (e.g., a +Z direction), compared to a surface of the side member 240. In an embodiment, the first support member 230a may be formed of a transparent material such as glass, glasstic, or ceramic, and the first cover glass 212a may be disposed so as to feel as if it is floating relative to the housing 210.

In an embodiment, the second connection member 220b may be connected to the inside of the side member 240 and support at least a portion of the second cover glass 212b. For example, the second connection member 220b may have a structure extending along the inner rim of the side member 240.

In an embodiment, the second support member 230b may be connected to the second connection member 220b and support an edge of the second cover glass 212b. The second support member 230b may have a structure extending along the second connection member 220b. In an embodiment, among surfaces of the second cover glass 212b and the second support member 230b, a surface the rear surface 210b faces may protrude further in a direction the rear surface 210b faces (e.g., a -Z direction), compared to the surface of the side member 240. In an embodiment, the second support member 230b may be formed of a transparent material such as glass, glasstic, or ceramic, and the second cover glass 212b may be disposed so as to feel as if it is floating relative to the housing 210.

In an embodiment, the electronic device 201 may include the display 261 (e.g., the display module 160 of FIG. 1). In an embodiment, the display 261 may be positioned on the front surface 210a. In an embodiment, the display 261 may be exposed through at least a portion of the first plate 211a. In an embodiment, the display 261 may have a shape that is substantially the same as the shape of an outer rim of the first plate 211a. In some embodiments, an edge of the display 261 may substantially coincide with the outer rim of the first plate 211a. In an embodiment, the display 261 may include a touch sensing circuit, a pressure sensor for sensing an intensity (pressure) of a touch, and/or a digitizer for detecting a magnetic-type stylus pen.

In an embodiment, the display 261 may include a screen display area 261a that is visually exposed to display content through pixels or a plurality of cells. In an embodiment, the screen display area 261a may include a sensing area 261a-1 and/or a camera area 261a-2. In this case, the sensing area 261a-1 may overlap at least a partial area of the screen display area 261a. The sensing area 261a-1 may allow transmission of an input signal related to a sensor module 276 (e.g., the sensor module 176 of FIG. 1). The sensing area 261a-1 may display content, similarly to the screen display area 261a that does not overlap the sensing area 261a-1. For example, the sensing area 261a-1 may display the content while the sensor module 276 is not operating. The camera area 261a-2 may overlap at least a partial area of the screen display area 261a. The camera area 261a-2 may allow transmission of an optical signal related to first camera modules 280a and 280b (e.g., the camera module 180 of FIG. 1). The camera area 261a-2 may display content, similarly to the screen display area 261a that does not overlap the camera area 261a-2. For example, the camera area 261a-2 may display content while the first camera modules 280a and 280b are not operating.

In an embodiment, the electronic device 201 may include an audio module 270 (e.g., the audio module 170 of FIG. 1). The audio module 270 may obtain sound from the outside of the electronic device 201. For example, the audio module 270 may be positioned on the side surface 211c of the housing 210. In an embodiment, the audio module 270 may obtain sound through at least one hole.

In an embodiment, the electronic device 201 may include the sensor module 276. The sensor module 276 may sense a signal applied to the electronic device 201. The sensor module 276 may be positioned, for example, on the front surface 210a of the electronic device 201. The sensor module 276 may form the sensing area 261a-1 in at least a portion of the screen display area 261a. The sensor module 276 may receive an input signal transmitted through the sensing area 261a-1 and generate an electrical signal based on the received input signal. For example, the input signal may have a designated physical quantity (e.g., heat, light, temperature, sound, pressure, or ultrasound). As another example, the input signal may include a signal related to biometric information (e.g., a fingerprint, a voice, and the like) of a user.

In an embodiment, the electronic device 201 may include camera modules 280a and 280b (e.g., the camera module 180 of FIG. 1). In an embodiment, the camera modules 280a and 280b may include a first camera module 280a, a second camera module 280b, and a flash 280c. In an embodiment, the first camera module 280a may be disposed to be exposed through the front surface 210a of the housing 210, and the second camera module 280b and the flash 280c may be disposed to be exposed through the rear surface 210b of the housing 210. In an embodiment, at least a portion of the first camera module 280a may be disposed in the housing 210 so as to be covered through the display 261. In an embodiment, the first camera module 280a may receive an optical signal transmitted through the camera area 261a-2. In an embodiment, the second camera module 280b may include a plurality of cameras (e.g., dual cameras, triple cameras, or quad cameras). In an embodiment, the flash 280c may include a light-emitting diode or a xenon lamp.

In an embodiment, the electronic device 201 may include a sound output module 255 (e.g., the sound output module 155 of FIG. 1). The sound output module 255 may output sound to the outside of the electronic device 201. For example, the sound output module 255 may output sound to the outside of the electronic device 201 through one or more holes formed in the side surface 211c of the housing 210.

In an embodiment, the electronic device 201 may include an input module 250 (e.g., the input module 150 of FIG. 1). The input module 250 may receive a manipulation signal of a user. The input module 250 may include, for example, at least one key input device disposed to be exposed on the side surface 211c of the housing 210.

In an embodiment, the electronic device 201 may include a connecting terminal 278 (e.g., the connecting terminal 178 of FIG. 1). In an example embodiment, the connecting terminal 278 may be disposed on the side surface 211c. For example, when the electronic device 201 is viewed in one direction (e.g., the +Y-axis direction of FIG. 2A), the connecting terminal may be disposed on a central portion of the side surface 211c, and the sound output module 255 may be disposed in a direction (e.g., a right direction) based on the connecting terminal 278.

In an embodiment, the electronic device 201 may include the PCBs 351 and 352, and a battery 389 (e.g., the battery 189 of FIG. 1). In an embodiment, the PCBs 351 and 352 may include the first circuit board 351 and the second circuit board 352. In this case, the first circuit board 351 may be accommodated in a first board slot 342a of the second support structure 342 and the second circuit board 352 may be accommodated in a second board slot 342b of the second support structure 342. In an embodiment, the battery 389 may be accommodated in a battery slot 345 of the second support structure 342 formed between the first board slot 342a and the second board slot 342b.

In an embodiment, a processor (e.g., the processor 120 of FIG. 1) may be disposed on the PCB 351 or 352. The processor may include, for example, one or more of a CPU, an AP, an ISP, a sensor hub processor, or a CP. In an embodiment, a wireless communication circuit (e.g., the wireless communication module 192 of FIG. 1) may be disposed on the PCB 351 or 352. The wireless communication circuit may perform communication with, for example, an external device (e.g., the electronic device 104 of FIG. 1). The electronic device 201 may include an antenna structure (e.g., the antenna module 197 of FIG. 1), and the wireless communication circuit may be electrically connected to the antenna structure. In an example embodiment, the wireless communication circuit may generate a signal to be transmitted through the antenna structure or detect a signal received through the antenna structure. In an embodiment, the PCBs 351 and 352 may include grounds, and the grounds of the PCBs 351 and 352 may function as a ground of the antenna structure implemented using the wireless communication circuit.

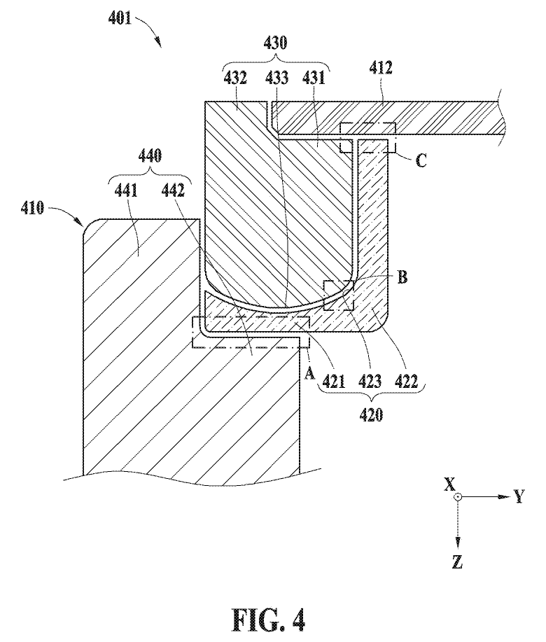

FIG. 4 is a partial cross-sectional view illustrating a side member, a connection member, a support member, and a cover glass of an electronic device according to an embodiment of the disclosure.

Referring to FIG. 4, an electronic device 401 (e.g., the electronic device 101 of FIG. 1 or the electronic device 201 of FIG. 2A) according to an embodiment may include a connection member 420 (e.g., the second connection member 220b of FIG. 2B) connected to a housing 410 (e.g., the housing 210 of FIG. 2A), and a support member 430 (e.g., the second support member 230b of FIG. 2B) connected to the connection member 420 and configured to support a cover glass 412 (e.g., the second cover glass 212b of FIG. 2B).

In an embodiment, the connection member 420 and the support member 430 may connect the cover glass 412 to only one of a front surface and a rear surface of the housing 410. In an embodiment, the cover glass 412 may be disposed on a first surface of the housing 410, wherein the first surface may be a rear surface of the housing 410 (e.g., the rear surface 210b of FIG. 2B). The connection member 420 may be connected to a side member 440 (e.g., the side member 240 of FIG. 2A). The support member 430 may be connected to the connection member 420 and support an edge of the cover glass 412.

In an embodiment, the connection member 420 may be seated on a seating portion 442 formed on an inner surface of the side member 440 in a stepped manner. Here, the seating portion 442 may be a portion extending inward of the electronic device 401 from a sidewall portion 441 exposed to the exterior of the electronic device 401, among a first support structure (e.g., the first support structure 341 of FIG. 3). The connection member 420 may include a first connection portion 421 and a second connection portion 422.

In an embodiment, the first connection portion 421 may be a portion supported by the seating portion 442 of the side member 440. The second connection portion 422 may be a portion extending from the first connection portion 421 toward a rear surface of the cover glass 412. With this structure, a space into which the support member 430 is inserted may be provided between the sidewall portion 441 of the side member 440 and the second connection portion 422.

In an embodiment, the connection member 420 may include a first connection surface 423 opposing the support member 430, and the support member 430 may include a second connection surface 433 opposing the connection member 420. In an embodiment, the first connection surface 423 and the second connection surface 433 may have shapes corresponding to each other. For example, as illustrated in FIG. 4, the first connection surface 423 may be a curved surface covering the second connection surface 433.

In an embodiment, the support member 430 may include a first support portion 431 and a second support portion 432. In an embodiment, the first support portion 431 may support the rear surface of the cover glass 412. A surface of the first support portion 431 supporting the cover glass 412 may be flat.

In an embodiment, the second support portion 432 may protrude further in a direction the second surface faces (e.g., a -Z direction), compared to the first support portion 431. The second support portion 432 may extend outward from the first support portion 431 and support an edge of the cover glass 412. With this structure, direct breakage or damage to the edge of the cover glass 412 due to dropping of the electronic device 401, external impact, or the like may be reduced.

In an embodiment, a surface of the second support portion 432 facing the exterior of the electronic device 401 and a surface of the cover glass 412 may be substantially coplanar. The cover glass 412 and the second support portion 432 may be surface-treated. For example, surfaces of the cover glass 412 and the second support portion 432 may be etched. Here, the etching may include various types of etching, such as chemical etching, sandblasting etching, or laser etching. A sense of heterogeneity between a surface of the second support portion 432 and the surface of the cover glass 412 may be reduced.

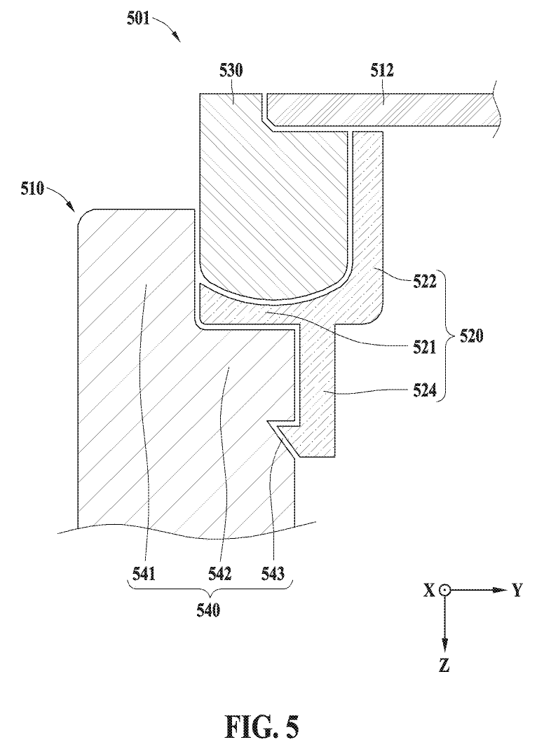

FIG. 5 is a partial cross-sectional view illustrating a side member, a connection member, a support member, and a cover glass of an electronic device according to an embodiment of the disclosure.

Referring to FIG. 5, an electronic device 501 (e.g., the electronic device 201 of FIG. 2A or the electronic device 401 of FIG. 4) according to an embodiment may include a connection member 520 (e.g., the second connection member 220b of FIG. 3 or the connection member 420 of FIG. 4) connected to a side member 540 (e.g., the side member 240 of FIG. 2A or the side member 440 of FIG. 4) of a housing 510 (e.g., the housing 210 of FIG. 2A or the housing 410 of FIG. 4), and a support member 530 (e.g., the second support member 230b of FIG. 2B or the support member 430 of FIG. 4) connected to the connection member 520 and configured to support a cover glass 512 (e.g., the second cover glass 212b of FIG. 2B or the cover glass 412 of FIG. 4). The cover glass 512 of the electronic device 501 may be connected to the side member 540 through the connection member 520 and the support member 530. The connection member 520 may include a first connection portion 521 (e.g., the first connection portion 421 of FIG. 4), a second connection portion 522 (e.g., the second connection portion 422 of FIG. 4), and a hook 524.

In an embodiment, the hook 524 may extend from the connection member 520 in a direction the second surface faces (e.g., a +Z direction). An engaging groove 543 into which the hook 524 is fitted may be formed in an inner surface of the side member 540. For example, the hook 524 may extend along the seating portion 542 of the side member 540 and be received in the engaging groove 543 formed in the seating portion 542. With this structure, a bonding strength between the side member 540 and the connection member 520 may be increased.

In an embodiment, a plurality of hooks 524 may be provided along a perimeter of the second connection member 520. A position of each of the plurality of hooks 524 protruding from the connection member 520 may be determined according to an arrangement situation of a battery (e.g., the battery 389 of FIG. 3) or the like disposed inside the housing 510.

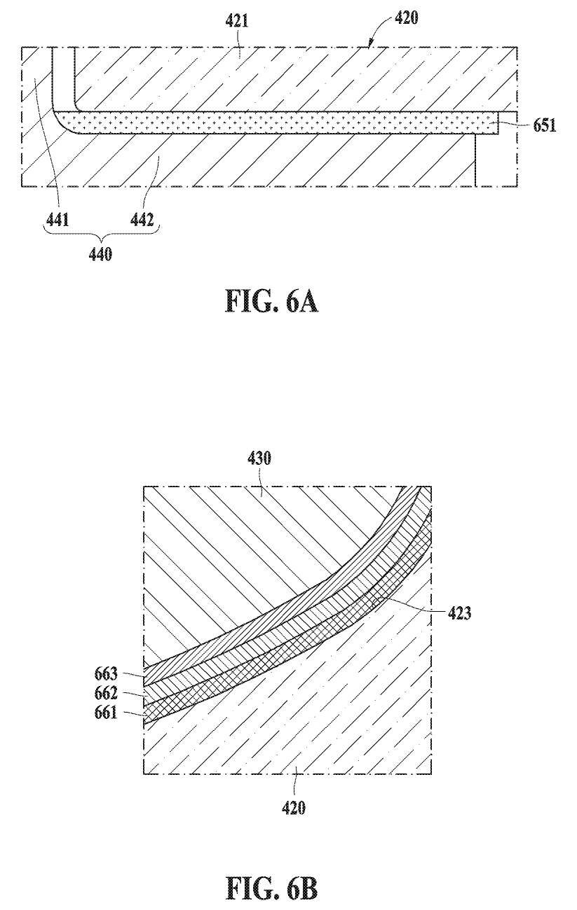

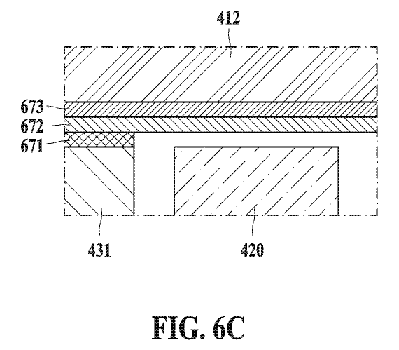

FIG. 6A is an enlarged cross-sectional view of a region A illustrated in FIG. 4 according to an embodiment of the disclosure, FIG. 6B is an enlarged cross-sectional view of a region B illustrated in FIG. 4 according to an embodiment of the disclosure, and FIG. 6C is an enlarged cross-sectional view of a region C illustrated in FIG. 4 according to an embodiment of the disclosure.

Referring to FIGS. 6A to 6C, an electronic device (e.g., the electronic device 401 of FIG. 4) according to an embodiment may include the side member 440, the connection member 420, the support member 430, and the cover glass 412. In an embodiment, the cover glass 412 may be supported by the support member 430, and the support member 430 may be connected to the connection member 420 connected to the side member 440 of a housing (e.g., the housing 410 of FIG. 4).

In an embodiment, the first connection portion 421 of the connection member 420 may be connected to the seating portion 442 through a first bonding layer 651. The first bonding layer 651 may be composed of an optically clear adhesive (OCA). A gap between the connection member 420 and the seating portion 442 may be filled by the first bonding layer 651. An amount of foreign substances such as liquid or dust penetrating between the connection member 420 and the seating portion 442 may be reduced. Although the first bonding layer 651 is illustrated in the drawings of the specification as being formed on the seating portion 442, it should be noted that the first bonding layer 651 may also be formed on a surface of the side member 440 opposing the first connection portion 421.

In an embodiment, the support member 430 may be connected to the connection member 420 by a second bonding layer 661. The second bonding layer 661 may be composed of an OCA, similar to the first bonding layer 651. The second bonding layer 661 may be disposed on at least a portion of the first connection surface 423.

In an embodiment, a first shielding layer 662 and a deposition layer 663 may be disposed on the support member 430. The deposition layer 663 may be disposed between the second connection surface 433 and the first shielding layer 662. The deposition layer 663 may be formed through a deposition process. The deposition process may include various types of deposition processes such as physical vapor deposition (PVD), chemical vapor deposition (CVD), or atomic layer deposition (ALD). The deposition layer 663 may have a high reflectance. Light reflected from the deposition layer 663 may pass through the support member 430 formed of a transparent material and be visible, thereby improving aesthetics of the electronic device.

In an embodiment, the first shielding layer 662 may be formed of an opaque material. The first shielding layer 662 may block an interior of the housing 410 from being visible through the support member 430 formed of a transparent material.

In an embodiment, the cover glass 412 may be connected to the support member 430 through a third bonding layer 671. For example, the third bonding layer 671 may be disposed between the first support portion 431 and the cover glass 412. The third bonding layer 671 may be composed of an OCA or formed by heat fusion. When the third bonding layer 671 is formed by heat fusion, a post-treatment process may be performed on a surface of the third bonding layer 671 after the heat fusion. Due to the third bonding layer 671, the connection strength of the cover glass 412 connected to the support member 430 may be increased, and the CMF (Color, Material, Finishing) characteristics of the cover glass 412 may be improved.

In an embodiment, a laminate layer 673 and a second shielding layer 672 may be disposed on the rear surface of the cover glass 412. The laminate layer 673 may be disposed between the cover glass 412 and the second shielding layer 672. The laminate layer 673 may be formed through various methods such as painting, digital printing, or laser marking. The laminate layer 673 may be formed of an opaque material. Light reflected from the laminate layer 673 may pass through the cover glass 412 formed of a transparent material and be visible. A color of the laminate layer 673 may be revealed to the exterior of the electronic device 401 through the cover glass 412.

In an embodiment, the second shielding layer 672 may be formed of an opaque material. The second shielding layer 672 may block the interior of the housing 410 from being visible through the cover glass 412 formed of a transparent material.

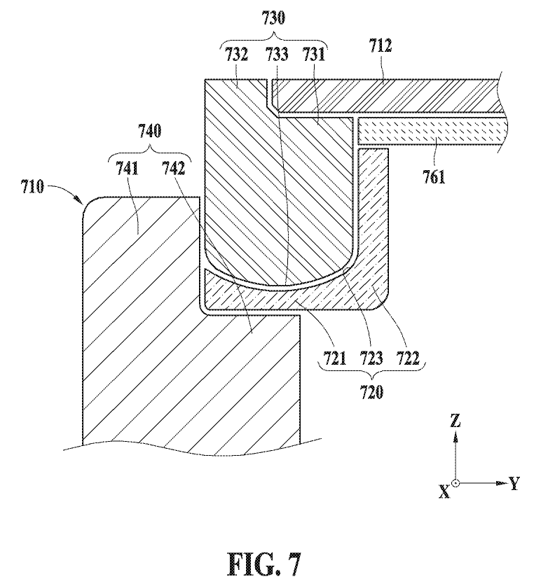

FIG. 7 is a partial cross-sectional view illustrating a side member, a connection member, a support member, a display, and a cover glass of an electronic device according to an embodiment of the disclosure.

Referring to FIG. 7, an electronic device 701 (e.g., the electronic device 201 of FIG. 2A or the electronic device 401 of FIG. 4) according to an embodiment may include a connection member 720 (e.g., the first connection member 220a of FIG. 3 or the connection member 420 of FIG. 4) connected to a housing 710 (e.g., the housing 210 of FIG. 2A or the housing 410 of FIG. 4), and a support member 730 (e.g., the first support member 230a of FIG. 2A or the support member 430 of FIG. 4) connected to the connection member 720 and configured to support a cover glass 712 (e.g., the first cover glass 212a of FIG. 2A or the cover glass 412 of FIG. 4).

In an embodiment, the connection member 720 and the support member 730 may connect the cover glass 712 to only one of a front surface and a rear surface of the housing 710. In an embodiment, the cover glass 712 may be disposed on a first surface of the housing 710, wherein the first surface may be a front surface of the housing 710 (e.g., the front surface 210a of FIG. 2A). The connection member 720 may be connected to a side member 740 (e.g., the side member 240 of FIG. 2A or the side member 440 of FIG. 4). The support member 730 may be connected to the connection member 720 and support an edge of the cover glass 712.

In an embodiment, the connection member 720 may be seated on a seating portion 742 (e.g., the seating portion 442 of FIG. 4) formed on an inner surface of the side member 740 in a stepped manner. The connection member 720 may include a first connection portion 721 (e.g., the first connection portion 421 of FIG. 4) and a second connection portion 722 (e.g., the second connection portion 422 of FIG. 4). A space into which the support member 730 is inserted may be provided between the sidewall portion 741 of the side member 740 and the second connection portion 722.

In an embodiment, the connection member 720 may include a first connection surface 723 (e.g., the first connection surface 423 of FIG. 4) opposing the support member 730, and the support member 730 may include a second connection surface 733 (e.g., the second connection surface 433 of FIG. 4) opposing the connection member 720. In an embodiment, the first connection surface 723 and the second connection surface 733 may have shapes corresponding to each other.

In an embodiment, the support member 730 may include a first support portion 731 (e.g., the first support portion 431 of FIG. 4) and a second support portion 732 (e.g., the second support portion 432 of FIG. 4). In an embodiment, the first support portion 731 may support a rear surface of the cover glass 712.

In an embodiment, the second support portion 732 may protrude further in a direction the first surface faces (e.g., a +Z direction), compared to the first support portion 731. The second support portion 732 may extend outward from the first support portion 731 and support the edge of the cover glass 712.

In an embodiment, a display 761 (e.g., the display 261 of FIG. 2A) may be disposed between the cover glass 712 and the first support portion 731. When a length of the display 761 in a direction parallel to a Y-axis is longer than a length illustrated in the drawings of the specification, it may be understood that a side surface of the first support portion 731 opposing the display 761 is recessed, and both ends of the display 761 are inserted into the recessed region.

In an embodiment, a surface of the second support portion 732 facing the exterior of the electronic device 701 and a surface of the cover glass 712 may be substantially coplanar. The cover glass 712 and the second support portion 732 may be surface-treated. For example, surfaces of the cover glass 712 and the second support portion 732 may be etched. Here, the etching may include various types of etching, such as chemical etching, sandblasting etching, or laser etching.

In an embodiment, in order to reduce performance degradation of the display 761, the surface treatment may not be performed on an entire surface of the cover glass 712 facing the exterior of the electronic device 701, but may be performed only on a portion of the surface close to the edge.

In an embodiment, the connection member 720 may be connected to the side member 740 by a first bonding layer (e.g., the first bonding layer 651 of FIG. 6A). The support member 730 may be connected to the connection member 720 by a second bonding layer (e.g., the second bonding layer 661 of FIG. 6B). A deposition layer (e.g., the deposition layer 663 of FIG. 6B) and a first shielding layer (e.g., the first shielding layer 662 of FIG. 6B) may be disposed on the second connection surface 733.

In an embodiment, the cover glass 712 may be connected to the support member 730 by a third bonding layer (e.g., the third bonding layer 671 of FIG. 6C). Meanwhile, since the cover glass 712 is disposed on the display 761, a laminate layer (e.g., the laminate layer 673 of FIG. 6C) and a second shielding layer (e.g., the second shielding layer 672 of FIG. 6C) may not be disposed on the rear surface of the cover glass 712.

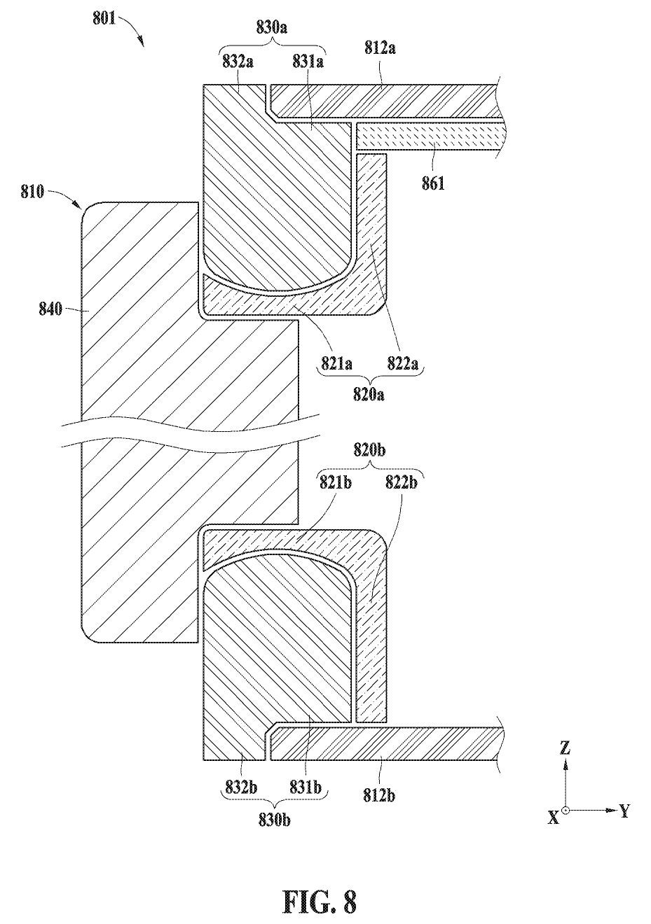

FIG. 8 is a cross-sectional view illustrating a side member, a connection member, a support member, and a cover glass of an electronic device according to an embodiment of the disclosure.

Referring to FIG. 8, a connection member 820a, 820b and a support member 830a, 830b may be disposed on each of a front surface and a rear surface of an electronic device 801 (e.g., the electronic device 201 of FIG. 2A) according to an embodiment.

In an embodiment, the electronic device 801 may include a first connection member 820a (e.g., the first connection member 220a of FIG. 3) connected to a housing 810 (e.g., the housing 210 of FIG. 2A), and a first support member 830a (e.g., the first support member 230a of FIG. 2A) connected to the first connection member 820a and configured to support a first cover glass 812a (e.g., the first cover glass 212a of FIG. 2A) disposed on a first surface. Surfaces of the first cover glass 812a and the first support member 830a may protrude in a direction the first surface faces (e.g., a +Z direction), compared to a surface of a side member 840 (e.g., the side member 240 of FIG. 2A). A display 861 may be disposed on the first surface.

In an embodiment, the electronic device 801 may include a second connection member 820b (e.g., the second connection member 220b of FIG. 3) connected to the housing 810 (e.g., the housing 210 of FIG. 2A), and a second support member 830b (e.g., the second support member 230b of FIG. 2B) connected to the second connection member 820b and configured to support a second cover glass 812b (e.g., the second cover glass 212b of FIG. 2B) disposed on a second surface. Surfaces of the second cover glass 812b and the second support member 830b may protrude in a direction the second surface faces (e.g., a -Z direction), compared to the surface of the side member 840.

In an embodiment, the first connection member 820a may include a first-first connection portion 821a supported by the housing 810, and a first-second connection portion 822a extending from the first-first connection portion 821a toward a rear surface of the first cover glass 812a.

In an embodiment, the second connection member 820b may include a second-first connection portion 821b supported by the housing 810, and a second connection portion 822b extending from the second-first connection portion 821b.

In an embodiment, the first support member 830a may include a first-first support portion 831a and a first-second support portion 832a. The first-first support portion 831a may support a rear surface of the first cover glass 812a. The first-second support portion 832a may extend outward from the first-first support portion 831a and support an edge of the first cover glass. The first-second support portion 832a may protrude further in a direction the first surface faces (a +Z direction) than the first-first support portion 831a.

In an embodiment, the second support member 830b may include a second-first support portion 831b and a second-second support portion 832b. The second-first support portion 831b may support a rear surface of the second cover glass 812b. The second-second support portion 832b may extend outward from the second-first support portion 831b and support an edge of the second cover glass. The second-second support portion 832b may protrude further in a direction the second surface faces (a -Z direction) than the second-first support portion 831b.

An electronic device 101; 201; 401; 501; 701; 801 according to an embodiment may include a housing 210; 410; 510; 710; 810 including a first surface, a second surface opposite to the first surface, and a side member 240; 440; 540; 740; 840 surrounding at least a portion of an inner space between the first surface and the second surface, a cover glass 212a; 212b; 412; 512; 712; 812a; 812b disposed on the first surface of the housing 210; 410; 510; 710; 810, a connection member 220a; 220b; 420; 520; 720; 820a; 820b connected to an inside of the side member 240; 440; 540; 740; 840 and configured to support at least a portion of the cover glass 212a; 212b; 412; 512; 712; 812a; 812b, and a support member 230a; 230b; 430; 530; 730; 830a; 830b connected to the connection member 220a; 220b; 420; 520; 720; 820a; 820b and configured to support an edge of the cover glass 212a; 212b; 412; 512; 712; 812a; 812b, wherein surfaces of the cover glass 212a; 212b; 412; 512; 712; 812a; 812b and the support member 230a; 230b; 430; 530; 730; 830a; 830b may protrude in a direction the first surface faces, compared to a surface of the side member 240; 440; 540; 740; 840.

In an embodiment, the side member 240; 440; 540; 740; 840 may include a seating portion 242; 442; 542; 742 formed on an inner surface thereof in a stepped manner, and the connection member 220a; 220b; 420; 520; 720; 820a; 820b may include a first connection portion 421; 521; 721; 821a; 821b seated on the seating portion 242; 442; 542; 742, and a second connection portion 422; 522; 722; 822a; 822b extending from the first connection portion 421; 521; 721; 821a; 821b toward a rear surface of the cover glass 212a; 212b; 412; 512; 712; 812a; 812b.

In an embodiment, the electronic device 101; 201; 401; 501; 701; 801 may further include a first bonding layer 651 disposed between the seating portion 242; 442; 542; 742 and the first connection portion 421; 521; 721; 821a; 821b.

In an embodiment, the support member 230a; 230b; 430; 530; 730; 830a; 830b may be connected to the connection member 220a; 220b; 420; 520; 720; 820a; 820b so as to be positioned between the side member 240; 440; 540; 740; 840 and the second connection portion 422; 522; 722; 822a; 822b of the connection member 220a; 220b; 420; 520; 720; 820a; 820b.

In an embodiment, based on a cross-section, the connection member 220a; 220b; 420; 520; 720; 820a; 820b may include a first connection surface 423; 723 facing the first surface, the support member 230a; 230b; 430; 530; 730; 830a; 830b may include a second connection surface 433; 733 facing the second surface and opposite to the first connection surface 423; 723, and the first connection surface 423; 723 and the second connection surface 433; 733 may have shapes corresponding to each other.

In an embodiment, the first connection surface 423; 723 and the second connection surface 433; 733 may form a curved surface.

In an embodiment, the electronic device 101; 201; 401; 501; 701; 801 may further include a second bonding layer 661 disposed between the first connection surface 423; 723 and the second connection surface 433; 733.

In an embodiment, the electronic device 101; 201; 401; 501; 701; 801 may further include a first shielding layer 662 disposed on the second connection surface 433; 733 of the support member 230a; 230b; 430; 530; 730; 830a; 830b, and a deposition layer 663 disposed between the second connection surface 433; 733 and the first shielding layer 662.

In an embodiment, the support member 230a; 230b; 430; 530; 730; 830a; 830b may include a first support portion 431; 731; 831a; 831b configured to support a rear surface of the cover glass 212a; 212b; 412; 512; 712; 812a; 812b, and a second support portion 432; 732; 832a; 832b extending outward from the first support portion 431; 731; 831a; 831b and configured to support an edge of the cover glass 212a; 212b; 412; 512; 712; 812a; 812b, wherein the second support portion 432; 732; 832a; 832b may protrude further in a direction of the first surface than the first support portion 431; 731; 831a; 831b.

In an embodiment, a surface of the second support portion 432; 732; 832a; 832b and a surface of the cover glass 212a; 212b; 412; 512; 712; 812a; 812b may be substantially coplanar.

In an embodiment, the cover glass 212a; 212b; 412; 512; 712; 812a; 812b and the second support portion 432; 732; 832a; 832b of the support member 230a; 230b; 430; 530; 730; 830a; 830b may be surface-treated.

In an embodiment, the electronic device 101; 201; 401; 501; 701; 801 may further include a third bonding layer 671 disposed between the first support portion 431; 731; 831a; 831b and the cover glass 212a; 212b; 412; 512; 712; 812a; 812b.

In an embodiment, the electronic device 101; 201; 401; 501; 701; 801 may further include a second shielding layer 672 disposed on a rear surface of the cover glass 212a; 212b; 412; 512; 712; 812a; 812b, and a laminate layer 673 disposed between the cover glass 212a; 212b; 412; 512; 712; 812a; 812b and the second shielding layer 672.

In an embodiment, the connection member 220a; 220b; 420; 520; 720; 820a; 820b may further include a hook 524 extending in a direction the second surface faces, and an engaging groove 543 into which the hook 524 is fitted may be formed in an inner surface of the side member 240; 440; 540; 740; 840.

In an embodiment, the support member 230a; 230b; 430; 530; 730; 830a; 830b may be formed of a transparent material.

An electronic device 101; 201; 401; 501; 701; 801 according to an embodiment may include a housing 210; 410; 510; 710; 810 including a first surface, a second surface opposite to the first surface, and a side member 240; 440; 540; 740; 840 surrounding at least a portion of an inner space between the first surface and the second surface, a first cover glass 212a; 812a disposed on the first surface, a second cover glass 212b; 812b disposed on the second surface, a first connection member 220a; 820a connected to an inside of the side member 240; 440; 540; 740; 840 and configured to support at least a portion of the first cover glass 212a; 812a, a second connection member 220b; 820b connected to the inside of the side member 240; 440; 540; 740; 840 and configured to support at least a portion of the second cover glass 212b; 812b, a first support member 230a; 830a connected to the first connection member 220a; 820a and configured to support an edge of the first cover glass 212a; 812a, and a second support member 230b; 830b connected to the second connection member 220b; 820b and configured to support an edge of the second cover glass 212b; 812b. In an embodiment, surfaces of the first cover glass 212a; 812a and the first support member 230a; 830a may protrude in a direction the first surface faces, compared to a surface of the side member 240; 440; 540; 740; 840, and surfaces of the second cover glass 212b; 812b and the second support member 230b; 830b may protrude in a direction the second surface faces, compared to the surface of the side member 240; 440; 540; 740; 840.

In an embodiment, the first support member 230a; 830a may include a first-first support portion 831a configured to support a rear surface of the first cover glass 212a; 812a, and a first-second support portion 832a extending outward from the first-first support portion 831a and configured to support an edge of the first cover glass 212a; 812a, wherein the first-second support portion 832a may protrude further in a direction the first surface faces than the first-first support portion 831a.

In an embodiment, a surface of the first-second support portion 832a and a surface of the first cover glass 212a; 812a may be substantially coplanar.

In an embodiment, the first support member 230a; 830a and the second support member 230b; 830b may be formed of a transparent material.

An electronic device 101; 201; 401; 501; 701; 801 according to an embodiment may include a housing 210; 410; 510; 710; 810 including a first surface, a second surface opposite to the first surface, and a side member 240; 440; 540; 740; 840 surrounding at least a portion of an inner space between the first surface and the second surface, a display 261; 761; 861 disposed on the first surface of the housing 210; 410; 510; 710; 810, a cover glass 212a; 212b; 412; 512; 712; 812a; 812b disposed on the second surface of the housing 210; 410; 510; 710; 810, a connection member 220a; 220b; 420; 520; 720; 820a; 820b connected to an inside of the side member 440 and configured to support at least a portion of the cover glass 212a; 212b; 412; 512; 712; 812a; 812b, and a support member 230a; 230b; 430; 530; 730; 830a; 830b formed of a transparent material, connected to the connection member 220a; 220b; 420; 520; 720; 820a; 820b, and configured to support an edge of the cover glass 212a; 212b; 412; 512; 712; 812a; 812b, wherein surfaces of the cover glass 212a; 212b; 412; 512; 712; 812a; 812b and the support member 230a; 230b; 430; 530; 730; 830a; 830b may protrude in a direction the second surface faces, compared to a surface of the side member 240; 440; 540; 740; 840. In an embodiment, the support member 230a; 230b; 430; 530; 730; 830a; 830b may include a first support portion 431; 731; 831a; 831b configured to support a rear surface of the cover glass 212a; 212b; 412; 512; 712; 812a; 812b, and a second support portion 432; 732; 832a; 832b extending outward from the first support portion 431; 731; 831a; 831b and configured to support an edge of the cover glass 212a; 212b; 412; 512; 712; 812a; 812b, wherein the second support portion 432; 732; 832a; 832b may protrude further in a direction the second surface faces than the first support portion 431; 731; 831a; 831b.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a housing (comprising a first surface, a second surface opposite to the first surface, and a side member surrounding at least a portion of an inner space between the first surface and the second surface;
a cover glass disposed on the first surface of the housing;
a connection member connected to an inside of the side member and configured to support at least a portion of the cover glass; and
a support member connected to the connection member and configured to support an edge of the cover glass,
wherein surfaces of the cover glass and the support member protrude in a direction the first surface faces, compared to a surface of the side member.

2. The electronic device of claim 1,
wherein the side member comprises a seating portion formed on an inner surface thereof in a stepped manner, and
wherein the connection member comprises:
a first connection portion seated on the seating portion, and
a second connection portion extending from the first connection portion toward a rear surface of the cover glass.

3. The electronic device of claim 2, further comprising:
a first bonding layer disposed between the seating portion and the first connection portion.

4. The electronic device of claim 3, wherein the support member is connected to the connection member so as to be positioned between the side member and the second connection portion of the connection member.

5. The electronic device of claim 1,
wherein, based on a cross-section,
the connection member comprises a first connection surface facing the first surface,
the support member comprises a second connection surface facing the second surface and opposite to the first connection surface, and
the first connection surface and the second connection surface have shapes corresponding to each other.

6. The electronic device of claim 5, wherein the first connection surface and the second connection surface form a curved surface.

7. The electronic device of claim 6, further comprising:
a second bonding layer disposed between the first connection surface and the second connection surface.

8. The electronic device of claim 7, further comprising:
a first shielding layer disposed on the second connection surface of the support member; and
a deposition layer disposed between the second connection surface and the first shielding layer.

9. The electronic device of claim 8,
wherein the support member comprises:
a first support portion configured to support a rear surface of the cover glass, and
a second support portion extending outward from the first support portion and configured to support an edge of the cover glass, and
wherein the second support portion protrudes further in a direction of the first surface than the first support portion.

10. The electronic device of claim 9, wherein a surface of the second support portion and a surface of the cover glass are substantially coplanar.

11. The electronic device of claim 10, wherein the cover glass and the second support portion of the support member are surface-treated.

12. The electronic device of claim 11, further comprising:
a third bonding layer disposed between the first support portion and the cover glass.

13. The electronic device of claim 12, further comprising:
a second shielding layer disposed on a rear surface of the cover glass; and
a laminate layer disposed between the cover glass and the second shielding layer.

14. The electronic device of claim 13, wherein the connection member further comprises:
a hook extending in a direction the second surface faces; and
an engaging groove into which the hook is fitted is formed in an inner surface of the side member.

15. The electronic device of claim 14, wherein the support member is formed of a transparent material.

16. An electronic device, comprising:
a housing comprising a first surface, a second surface opposite to the first surface, and a side member surrounding at least a portion of an inner space between the first surface and the second surface;
a first cover glass disposed on the first surface;
a second cover glass disposed on the second surface;
a first connection member connected to an inside of the side member and configured to support at least a portion of the first cover glass;
a second connection member connected to the inside of the side member and configured to support at least a portion of the second cover glass;
a first support member connected to the first connection member and configured to support an edge of the first cover glass; and
a second support member connected to the second connection member and configured to support an edge of the second cover glass,
wherein surfaces of the first cover glass and the first support member protrude in a direction the first surface faces, compared to a surface of the side member, and
wherein surfaces of the second cover glass and the second support member protrude in a direction the second surface faces, compared to the surface of the side member.

17. The electronic device of claim 16,
wherein the first support member comprises:
a first-first support portion configured to support a rear surface of the first cover glass, and
a first-second support portion extending outward from the first-first support portion and configured to support an edge of the first cover glass, and
wherein the first-second support portion protrudes further in a direction the first surface faces than the first-first support portion.

18. The electronic device of claim 17, wherein a surface of the first-second support portion and a surface of the first cover glass are substantially coplanar.

19. The electronic device of claim 18, wherein the first support member and the second support member are formed of a transparent material.

20. An electronic device, comprising:
a housing comprising a first surface, a second surface opposite to the first surface, and a side member surrounding at least a portion of an inner space between the first surface and the second surface;
a display disposed on the first surface of the housing;
a cover glass disposed on the second surface of the housing;
a connection member connected to an inside of the side member and configured to support at least a portion of the cover glass; and
a support member formed of a transparent material, connected to the connection member, and configured to support an edge of the cover glass,
wherein surfaces of the cover glass and the support member protrude in a direction the second surface faces, compared to a surface of the side member,
wherein the support member comprises:
a first support portion configured to support a rear surface of the cover glass, and
a second support portion extending outward from the first support portion and configured to support an edge of the cover glass, and
wherein the second support portion protrudes further in a direction the second surface faces than the first support portion.
